(19) United States
(12) Patent Application Publication
(10) Pub. No.: US 2015/0014297 A1
(43) Pub. Date: Jan. 15, 2015

(54) HEATING PLATE HAVING THERMAL SHOCK RESISTANCE AND CORROSION RESISTANCE

(71) Applicant: KOREA INSTITUTE OF MACHINERY AND MATERIALS, Daejeon (KR)

(72) Inventors: Se-Jong Kim, Changwon-si (KR); Jung Hwan Lee, Changwon-si (KR)

(73) Assignee: KOREA INSTITUTE OF MACHINERY AND MATERIALS, Daejeon (KR)

(21) Appl. No.: 14/229,065

(22) Filed: Mar. 28, 2014

(30) Foreign Application Priority Data
Jul. 9, 2013 (KR) 10-2013-0080375

(51) Int. Cl. H05B 3/28; H01L 21/67

(52) U.S. Cl. CPC H05B 3/283; H01L 21/67103
USPC 219/444.1; 219/548

(57) ABSTRACT

Disclosed herein is a heating plate of a heating device for a semiconductor manufacturing process, including: a metal matrix, which is composed of a Ni—Fe—Co alloy, and in which a heating element is buried; a first ceramic layer formed on one side of the metal matrix; and a second ceramic layer formed on the other side and circumference of the metal matrix. According to the heating plate for a semiconductor manufacturing process of the present invention, even when thermal shock caused by repetition of heating and cooling is applied to the metal matrix composed of a Ni—Fe—Co alloy, the heating plate can exhibit excellent thermal shock resistance because the consistency between the metal matrix and the ceramic layer made of AlN or the like is maintained, and can prevent the metal matrix from being damaged because the ceramic layer has excellent chemical resistance and wear resistance. Therefore, the heating device for a semiconductor manufacturing process, including the heating plate, can stably heat a semiconductor substrate during etching, deposition or the like. Further, this heating device is economically efficient compared to a conventional heating device including a heating plate made of aluminum nitride (AlN) as a major ingredient. Furthermore, this heating device can accomplish excellent temperature uniformity and can rapidly heat a semiconductor substrate to desired temperature in a small amount of electric power, when the ceramic layer is made of a material having high thermal conductivity such as AlN or the like.

### BACKGROUND OF THE INVENTION

1. Technical Field

The present invention relates to a heating plate having thermal shock resistance and corrosion resistance of a heating device for a semiconductor manufacturing process, and to a heating device including the same. More particularly, the present invention relates to a heating plate having thermal shock resistance and corrosion resistance of a heating device for a semiconductor manufacturing process, the heating plate including a metal matrix composed of a Ni—Fe—Co alloy, and to a heating device including the same.

2. Description of the Related Art

In a semiconductor manufacturing process using photolithography, a process of heating a semiconductor substrate is required in order to heat and cure a photosensitive film or to heat and calcine an insulating film having a low dielectric constant, such as a low-k film or the like, and this heating process is conducted by a heating device for a semiconductor manufacturing process.

In the heating device for a semiconductor manufacturing process, a heating plate, serving to support and heat a semiconductor substrate, has a structure in which a resistive heating element is buried in a ceramic material having high thermal conductivity and heat resistance, so this heating plate can have excellent durability and can maintain temperature uniformity on the supporting surface of the semiconductor substrate when heat emitted from the resistive heating element is diffused in the ceramic material.

Among ceramic materials used for a heating plating of a heating device for a semiconductor manufacturing process, aluminum nitride (AlN) is generally used because it has high thermal conductivity (theoretical thermal conductivity: about 320 W/mK), has a thermal expansion coefficient similar to that of silicon and exhibits high resistivity to halogen plasma. As a specific example, a conventional technology discloses a substrate heating device including: a ceramic plate which contains aluminum nitride as a major ingredient and on side of which is provided with a heating surface for placing a substrate; and a resistive heating element which is buried in the ceramic plate [Patent document 001].

However, when a heating plate of a heating device for a semiconductor manufacturing process is realized using aluminum nitride (AlN) as a major ingredient, there is a problem in that aluminum nitride is expensive, and thus economical efficiency is lowered, thereby increasing a manufacturing cost.

Therefore, it is required to develop a heating device for a semiconductor manufacturing process, which can satisfy economical efficiency as well as temperature uniformity and durability at the time of heating a substrate.

### PRIOR ART DOCUMENT

### Patent Document

(Patent document 0001) Korean Unexamined Application Publication No. 10-2006-0047165

### SUMMARY OF THE INVENTION

Accordingly, the present invention has been devised to solve the above-mentioned problems, and an object of the present invention is to provide a heating plate of a heating device for a semiconductor manufacturing process, which can provide excellent temperature uniformity, which can exhibit excellent thermal shock resistance even under a severe process condition of repeated heating and cooling and which can satisfy economical efficiency, and to provide a heating device including the heating plate.

In order to accomplish the above object, an aspect of the present invention provides a heating plate of a heating device for a semiconductor manufacturing process, including: a metal matrix, which is composed of a Ni—Fe—Co alloy, and in which a heating element is buried; a first ceramic layer formed on one side of the metal matrix; and a second ceramic layer formed on the other side and circumference of the metal matrix.

Here, the Ni—Fe—Co alloy may include nickel (Ni) 25-35 wt %, iron (Fe) 45-55 wt % and cobalt (Co) 10-20 wt %.

Further, the Ni—Fe—Co alloy may include nickel (Ni) 29.5 wt %, iron (Fe) 53.0 wt % and cobalt (Co) 17 wt %.

Further, the first ceramic layer may be made of AlN, Al₂O₃, ZrO₃ or Y₂O₃.

Further, the second ceramic layer may be made of AlN, Al₂O₃, ZrO₃ or Y₂O₃.

Further, the second ceramic layer may be formed by thermal spraying.

Further, the heating element may include a hot wire made of tungsten (W), molybdenum (Mo) or chromium (Cr).

Another aspect of the present invention provides a heating device for a semiconductor manufacturing process, including: a heating plate including a metal matrix, which is composed of a Ni—Fe—Co alloy, and in which a heating element is buried, a first ceramic layer formed on one side of the metal matrix, and a second ceramic layer formed on the other side and circumference of the metal matrix; and a shaft connected to the other side of the metal matrix.

Here, the shaft may be configured such that an electrode bar and a thermocouple are provided in a hollow formed therein along a length direction thereof.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a schematic sectional view showing a heating plate of a heating device for a semiconductor manufacturing process according to the present invention;

FIGS. 2A to 2C are optical micrographs showing the sections of test specimens fabricated by respectively forming ceramic layers (Al₂O₃ layers) on a Ni—Fe—Co alloy matrix, an A16061 matrix and an Al-45CF matrix, wherein the test specimens have received thermal shock by repeatedly heating these test specimens to 600° C. and then water-cooling them ten times;

FIG. 3 is a graph showing the results of leakage current changed and breakdown voltages of Al₂O₃ layers of test specimens fabricated by respectively forming ceramic layers (Al₂O₃ layers) on a Ni—Fe—Co alloy matrix, an A16061 matrix and an Al-45CF matrix, wherein the leakage current changed and breakdown voltages thereof were measured after applying thermal shock to the test specimens; and

FIG. 4 is a schematic sectional view showing a heating device for a semiconductor manufacturing process according to the present invention.

### DESCRIPTION OF THE PREFERRED EMBODIMENTS

Hereinafter, the present invention will be described in detail.

First, a heating plate of a heating device for a semiconductor manufacturing process according to the present invention will be described in detail with reference to the attached drawings.

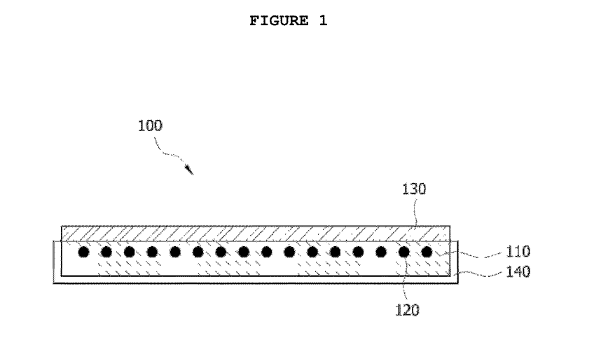

FIG. 1 is a schematic sectional view showing a heating plate of a heating device for a semiconductor manufacturing process according to the present invention. Referring to FIG. 1, the heating plate 100 includes: a metal matrix 110, which is located under a semiconductor substrate to be heated (not shown) to support the semiconductor substrate, and in which a heating element 120 is buried to heat the semiconductor substrate using the Joule heat generated from the heating element 120 by the electric current applied to the heating element 120; a first ceramic layer 130 formed on one side of the metal matrix 110; and a second ceramic layer 140 formed on the other side and circumference of the metal matrix 110.

In both sides of the metal matrix included in the heating plate of the present invention, one side thereof facing the first ceramic layer 130 is a heating surface, and a semiconductor substrate, which is to be heated in the step of heating a semiconductor substrate during a semiconductor manufacturing process, is placed on the first ceramic layer 130 formed on the heating surface. In both sides of the metal matrix, the other side thereof opposite to the heating surface is attached with a shaft, which is a tubular member for supporting the heating plate, thus constituting the following heating device for a semiconductor manufacturing process.

Meanwhile, the metal matrix may be composed of a Ni—Fe—Co alloy. In this case, the Ni—Fe—Co alloy may include nickel (Ni) 25-35 wt %, iron (Fe) 45-55 wt % and cobalt (Co) 10-20 wt %. As the Ni—Fe—Co alloy, a NILO alloy K (manufactured by Metals Corporation in U.S.A) including Ni) 29.5 wt %, iron (Fe) 53.0 wt % and cobalt (Co) 17 wt % may be used.

Since the metal matrix is composed of the above-mentioned Ni—Fe—Co alloy, the difference in thermal expansion coefficient between the metal matrix and the ceramic layer formed on the entire surface of the metal matrix is not large. Therefore, when the heating plate of the present invention is used in semiconductor manufacturing equipment in which heating and cooling are repeated, it can prevent the dielectric breakdown caused by thermal shock.

In relation to this, test specimens (refer to Table 1 below) were fabricated by respectively forming ceramic layers (Al₂O₃ layers) on other metal matrices including the metal matrix composed of the above-mentioned Ni—Fe—Co alloy, and then the thermal shock resistance of each of the ceramic layers formed on their respective metal matrices was evaluated.

TABLE 1

| | | Ceramic layer |
|---|---|---|
| Test | Matrix | (thickness: |
| specimen | (standard: 20 mm × 20 mm × 9 mm) | 150 μm) |
| 1 | Ni—Fe—Co alloy | Al₂O₃ layer |
| | (NILO alloy K: Ni 29.5 wt %, Fe 53.0 | |
| | wt % and Co 17 wt %) | |
| 2 | aluminum alloy (Al6061) | Al₂O₃ layer |
| 3 | Carbon fiber-reinforced aluminum | Al₂O₃ layer |
| | (Al—45CF) | |

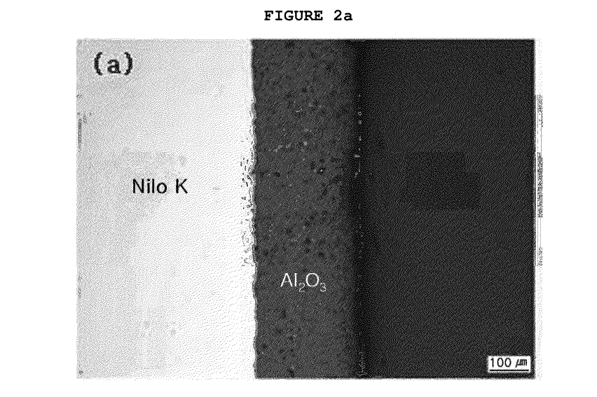

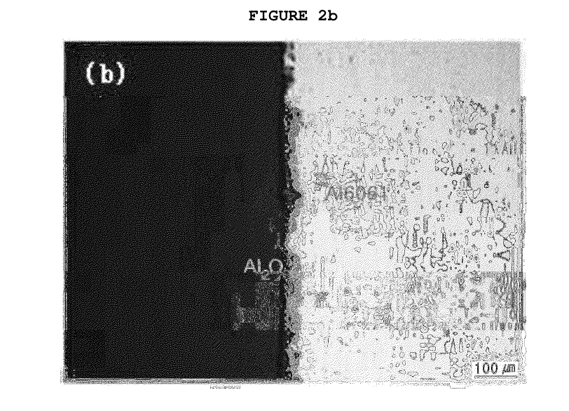

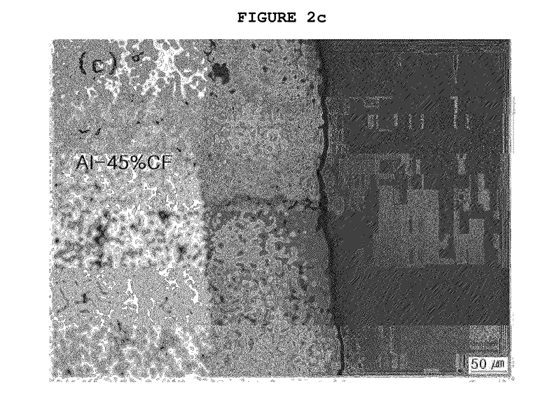

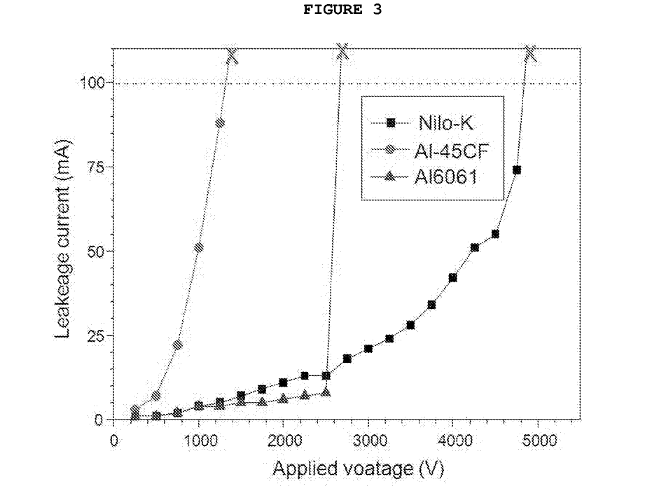

Specifically, the test specimens 1 to 3 were heated to 600° C., maintained at 600° C. for 10 min and then washed with water. These procedures were repeated ten times to apply thermal shock to the test specimens. Then, the sections of the thermally-shocked test specimens were observed by an optical microscope, and the results thereof are shown in FIG. 2A to 2C. Further, the breakdown voltages of the thermally-shocked test specimens were measured, and the results thereof are shown in FIG. 3.

Referring to FIGS. 2A to 2C, it can be ascertained that the Al₂O₃ layer (initial thickness: 100 μm) of the test specimen 2 did not remain (refer to FIG. 2B), and that the test specimen 3, the coating state of which had not been greatly problematic by observation with the naked eye, was cracked in the thickness direction thereof (refer to FIG. 2C). In contrast, it can be ascertained that, in the case of the test specimen 1 fabricated in Example, cracks were not observed in the Al₂O₃ layer thereof, and the interfacial state between the Al₂O₃ layer and the metal matrix was not greatly changed compared to that existing before thermal shock (refer to FIG. 2A).

Further, referring to FIG. 3, it can be ascertained that the test specimen 1 including the metal matrix composed of the above-mentioned Ni—Fe—Co alloy was broken down when an applied voltage reached about 5 kV, thus exhibiting the highest breakdown voltage. In contrast, it can be ascertained that, in the case of the test specimen 3, the leak current in the Al₂O₃ layer thereof was great at a low applied voltage, and this test specimen 3 was broken down at a low applied voltage of 2 kV, thus exhibiting the lowest breakdown voltage, and that the test specimen 2 had a low leakage current value compared to those of other test specimens at an applied voltage of 2.5 kV or lower, but was broken down at an applied voltage of 2.7 kV.

That is, since the metal matrix of the heating plate of the present invention is composed of the above-mentioned Ni—Fe—Co alloy, it is possible to prevent the ceramic layer from being striped or damaged by thermal shock, when this heating plate is used in semiconductor manufacturing equipment in which heating and cooling are repeated. Therefore, according to the present invention, it is possible to realize a heating plate having excellent durability.

The first ceramic layer included in the heating plate of the present invention is formed on the metal matrix. In this case, the first ceramic layer may be formed by a general coating layer forming method, such as physical vapor deposition (PVD), chemical vapor deposition (CVD) or the like, and may also be formed by a method of attaching a previously-prepared ceramic sheet to a metal matrix through brazing. The first ceramic layer may be made of AlN, Al₂O₃, ZrO₃ or Y₂O₃, and, preferably, may be made of AlN having high thermal conductivity. Further, the thickness of the first ceramic layer may be suitably adjusted in consideration of the protection of the metal matrix having poor chemical resistance, wear resistance, heat resistance and plasma resistance, the assurance of temperature uniformity of the heating plate, the prevention of breakdown of the ceramic layer, or the like.

The heating elements included in the heating plate of the present invention are buried in the metal matrix, and are arranged over the entire region of the metal matrix. In this case, in order to improve the temperature uniformity during heating, the arrangement form and density of the heating elements may be varied. For example, the temperature uniformity can be improved during heating by arranging the heating elements in the form of zigzag or circle to change the arrangement form thereof or by adjusting the horizontal intervals among the adjacent heating elements. Meanwhile, the kind of the heating element is not particularly limited. For instance, as the heating element, a sheath heater, which is formed by disposing a hot wire made of tungsten (W), molybdenum (Mo), chromium (Cr) or the like in the center of a metal tube and then filling the metal tube with magnesium oxide (MgO) powder having insulating properties, may be used, and, if necessary, a printed electrode may also be used.

The second ceramic layer included in the heating plate of the present invention is formed on the circumference and bottom surface of the metal matrix. In this case, the second ceramic layer may be formed by a general coating layer forming method, such as physical vapor deposition (PVD), chemical vapor deposition (CVD) or the like, and, preferably, may also be formed by thermal spraying in terms of the productivity and stability of a dielectric layer formed in this procedure. Preferably, the second ceramic layer may be formed by plasma spraying for melting, accelerating and coating dielectric material powder using plasma as a heat source. Specific examples of plasma spraying may include air plasma spraying (APS), vacuum plasma spraying (VPS), low pressure plasma spraying (LPPS), and the like. Meanwhile, the second ceramic layer may be made of AlN, Al₂O₃, ZrO₃ or Y₂O₃, and, preferably, may be made of Al₂O₃ having low thermal conductivity. Further, the thickness of the second ceramic layer may be suitably adjusted in consideration of the protection of the metal matrix having poor chemical resistance, wear resistance, heat resistance and plasma resistance, the assurance of temperature uniformity of the heating plate, the prevention of breakdown of the ceramic layer, or the like.

Next, a heating device for a semiconductor manufacturing process according to the present invention will be described in detail with reference to the attached drawings.

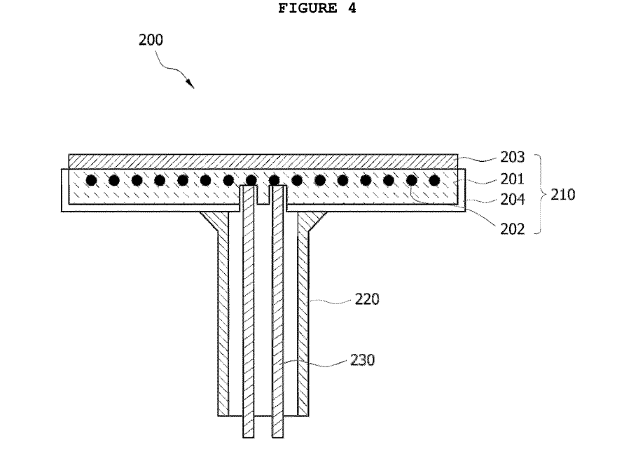

FIG. 4 is a schematic sectional view showing a heating device for a semiconductor manufacturing process according to the present invention. The heating device 200 for a semiconductor manufacturing process includes: the above-mentioned heating plate 210 including a metal matrix 201 buried and provided therein with a heating element 202, a first ceramic layer 203 formed on one side of the metal matrix 201, and a second ceramic layer 204 formed on the other side and circumference of the metal matrix 201; and a shaft 220 connected to the other side of the metal matrix 201.

The shaft 220 is a tubular member serving to support the heating plate 210. The shaft 220 is connected with the heating plate 210 by attaching the shaft 220 to one side of the metal matrix 201 opposite to the other side (heating surface) thereof facing the first ceramic layer 203, thus constituting the heating device for a semiconductor manufacturing process according to the present invention.

In this case, the method of attaching the shaft 220 to the heating plate 210 is not particularly limited. For example, the shaft 220 may be attached to the heating plate 210 by applying an adhesive to one side or both side of the heating plate 210 or the shaft 220 to connected the heating plate 210 with the shaft 220 and then heat-treating them, by soldering the heating plate 210 and the shaft 220, by mechanically connecting the heating plate 210 with the shaft 220, or the like.

Meanwhile, as shown in FIG. 4, the shaft 220 may be configured such that an electrode bar 230 for rapidly supplying power to the heating elements 202 is provided in a hollow formed therein along a length direction thereof, and, if necessary, a thermocouple is additionally provided in the hollow. Meanwhile, the end of the electrode bar is connected with the terminal of the heating elements by attaching them using soldering or by mechanically attaching them via screwing.

According to the heating plate for a semiconductor manufacturing process of the present invention, even when thermal shock caused by repetition of heating and cooling is applied to the metal matrix composed of a Ni—Fe—Co alloy, the heating plate can exhibit excellent thermal shock resistance because the consistency between the metal matrix and the ceramic layer made of AlN or the like is maintained, and can prevent the metal matrix from being damaged because the ceramic layer has excellent chemical resistance and wear resistance.

Therefore, the heating device for a semiconductor manufacturing process, including the heating plate, can stably heat a semiconductor substrate during etching, deposition or the like. Further, this heating device is economically efficient compared to a conventional heating device including a heating plate made of aluminum nitride (AlN) as a major ingredient. Furthermore, this heating device can accomplish excellent temperature uniformity and can rapidly heat a semiconductor substrate to desired temperature in a small amount of electric power, when the ceramic layer is made of a material having high thermal conductivity such as AlN or the like.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A heating plate of a heating device for a semiconductor manufacturing process, comprising:
a metal matrix, which is composed of a Ni—Fe—Co alloy, and in which a heating element is buried;
a first ceramic layer formed on one side of the metal matrix; and
a second ceramic layer formed on the other side and circumference of the metal matrix.

2. The heating plate of claim 1, wherein the Ni—Fe—Co alloy comprises nickel (Ni) 25-35 wt %, iron (Fe) 45-55 wt % and cobalt (Co) 10-20 wt %.

3. The heating plate of claim 2, wherein the Ni—Fe—Co alloy comprises nickel (Ni) 29.5 wt %, iron (Fe) 53.0 wt % and cobalt (Co) 17 wt %.

4. The heating plate of claim 1, wherein the first ceramic layer is made of AlN, Al₂O₃, ZrO₃ or Y₂O₃.

5. The heating plate of claim 1, wherein the second ceramic layer is made of AlN, Al₂O₃, ZrO₃ or Y₂O₃.

6. The heating plate of claim 1, wherein the second ceramic layer is formed by thermal spraying.

7. The heating plate of claim 1, wherein the heating element comprises a hot wire made of tungsten (W), molybdenum (Mo) or chromium (Cr).

8. A heating device for a semiconductor manufacturing process, comprising:
a heating plate including a metal matrix, which is composed of a Ni—Fe—Co alloy, and in which a heating element is buried, a first ceramic layer formed on one side of the metal matrix, and a second ceramic layer formed on the other side and circumference of the metal matrix; and
a shaft connected to the other side of the metal matrix.

9. The heating device of claim 8, wherein the shaft is configured such that an electrode bar and a thermocouple are provided in a hollow formed therein along a length direction thereof.
